(19) United States
(12) Patent Application Publication
(10) Pub. No.: US 2022/0045258 A1
(43) Pub. Date: Feb. 10, 2022

(54) METHOD FOR MANUFACTURING INTERMEDIATE BODY FOR THERMOELECTRIC CONVERSION MODULE

(71) Applicant: LINTEC CORPORATION, Itabashi-ku (JP)

(72) Inventors: Yuta SEKI, Kawasaki-shi (JP); Kunihisa KATO, Warabi-shi (JP); Tsuyoshi MUTO, Saitama-shi (JP); Yuma KATSUTA, Gyoda-shi (JP)

(73) Assignee: LINTEC CORPORATION, Itabashi-ku (JP)

(21) Appl. No.: 17/281,405

(22) PCT Filed: Oct. 2, 2019
(86) PCT No.: PCT/JP2019/038841

§ 371 Date: Mar. 30, 2021

(30) Foreign Application Priority Data
Oct. 3, 2018 (JP) 2018-188353

(51) Int. Cl. H01L 35/34; H01L 35/32; H01L 35/16

(52) U.S. Cl. CPC H01L 35/34; H01L 35/16; H01L 35/32

(57) ABSTRACT

A method for producing an intermediate for thermoelectric conversion modules may avoid a supporting substrate, enabling annealing of a thermoelectric semiconductor material in a form avoiding a joint to an electrode, and enabling annealing of a thermoelectric semiconductor material at an optimum temperature. Such methods may produce an intermediate for thermoelectric conversion modules containing a P-type thermoelectric and an N-type thermoelectric element layer of a thermoelectric semiconductor composition, and include (A) forming the P-type thermoelectric element layer and the N-type thermoelectric element layer on a substrate; (B) annealing the P-type and N-type thermoelectric element layer formed in (A); (C) forming a sealant layer containing a curable resin or a cured product thereof, on the P-type and N-type thermoelectric element layer annealed in (B); and (D) peeling the P-type and the N-type thermoelectric element layer and also the sealant layer formed in (B) and (C) from the substrate.

### TECHNICAL FIELD

The present invention relates to a method for producing an intermediate for thermoelectric conversion modules.

### BACKGROUND ART

Heretofore, there is known a device that enables direct interconversion between heat energy and electric energy by a thermoelectric conversion module having a thermoelectric effect such as a Seebeck effect and a Peltier effect, as one means of effective energy utilization.

As the thermoelectric conversion module, a configuration of a so-called in-plane-type thermoelectric conversion device is known. In general, the in-plane-type device has P-type thermoelectric elements and N-type thermoelectric elements as aligned alternately in the in-plane direction of a supporting substrate and is, for example, so configured that the lower parts or the upper parts of the joint regions between the two thermoelectric elements are bonded in series via an electrode therebetween.

In such situations, there are various demands for practical use of such thermoelectric conversion module, for example, for improving the flexibility of thermoelectric conversion modules, thinning the modules, improving the thermoelectric performance thereof, and reduction in material costs. For satisfying these demands, for example, a resin substrate of polyimide or the like is used as a supporting substrate for thermoelectric conversion modules from the viewpoint of heat resistance and flexibility thereof. Further, a thin film of a bismuth telluride material is used as an N-type thermoelectric semiconductor material and a P-type thermoelectric semiconductor material from the viewpoint of thermoelectric performance thereof, and as the electrode, a Cu electrode having a high thermal conductivity and a low resistance is used (PTLs 1 and 2).

### CITATION LIST

### Patent Literature

PTL 1: JP 2010-192764
PTL 2: JP 2012-204452

### SUMMARY OF INVENTION

### Technical Problem

As described above, however, in the case where a bismuth telluride material is used as the thermoelectric semiconductor material to be contained in the thermoelectric conversion material formed of a thermoelectric semiconductor composition, and where a Cu electrode or an Ni electrode is used as an electrode and a polyimide or the like resin is used as a supporting substrate for satisfying the demands for improving the flexibility of thermoelectric conversion modules, thinning the modules and improving the thermoelectric performance thereof, it has been found as a result of the present inventors' investigations that, for example, in a step of annealing the thermoelectric conversion module at a high temperature of 400° C. or so, there occurs another problem in that an alloy layer is formed by diffusion in the joint region between the thermoelectric semiconductor material contained in a thermoelectric conversion material and the Cu electrode or the Ni electrode and, as a result, the electrode is cracked or peeled to thereby increase the electric resistance value between the thermoelectric conversion material and the Cu electrode to worsen the thermoelectric performance. In addition to this, even in the case where a substrate using a polyimide or the like heat-resistant resin is used as the supporting substrate, the substrate could not maintain heat resistance up to an optimum annealing temperature (that is, a process temperature at which the thermoelectric performance can be exhibited maximally) that depends on the thermoelectric semiconductor material contained in the P-type thermoelectric element layer or an N-type thermoelectric element layer, as the case may be, and for this reason, the thermoelectric semiconductor material could not be subjected to optimum annealing treatment.

The present invention has been made in consideration of the situation as above, and an object thereof is to provide a method for producing an intermediate for thermoelectric conversion modules which does not require a supporting substrate, which enables annealing treatment of a thermoelectric semiconductor material in a form not having a joint to an electrode, and which enables annealing of a thermoelectric semiconductor material at an optimum annealing temperature.

### Solution to Problem

The present inventors have assiduously made repeated studies for solving the above-mentioned problems and, as a result, have found out a production method for an intermediate for thermoelectric conversion modules, which includes forming predetermined pattern layers of a P-type thermoelectric element layer and an N-type thermoelectric element layer on a substrate, then annealing them at an optimum annealing temperature, and laminating a sealant layer thereon, and thereafter peeling the resultant laminate of the P-type thermoelectric element layer and the N-type thermoelectric element layer and the sealant layer from the substrate to give an intermediate for thermoelectric conversion modules that does not require an already-existing supporting substrate and has been annealed in a form where the P-type thermoelectric element layer and the N-type thermoelectric element layer do not have a joint to an electrode, and have completed the present invention.

Specifically, the present invention provides the following (1) to (9):

(1) A method for producing an intermediate for thermoelectric conversion modules that contains a P-type thermoelectric element layer and an N-type thermoelectric element layer of a thermoelectric semiconductor composition, the method including (A) a step of forming the P-type thermoelectric element layer and the N-type thermoelectric element layer on a substrate, (B) a step of annealing the P-type thermoelectric element layer and the N-type thermoelectric element layer formed in the step (A), (C) a step of forming a sealant layer containing a curable resin or a cured product thereof, on the P-type thermoelectric element layer and the N-type thermoelectric element layer annealed in the step (B), and (D) a step of peeling the P-type thermoelectric element layer and the N-type thermoelectric element layer and also the sealant layer formed in the steps (B) and (C) from the substrate.
(2) The method for producing an intermediate for thermoelectric conversion modules according to the above (1), further including a step of forming an electrode on the annealed P-type thermoelectric element layer and N-type thermoelectric element layer.
(3) The method for producing an intermediate for thermoelectric conversion modules according to the above (1) or (2), wherein the curable resin is a thermosetting resin or an energy ray-curable resin.
(4) The method for producing an intermediate for thermoelectric conversion modules according to any of the above (1) to (3), wherein the thermosetting resin is an epoxy resin.
(5) The method for producing an intermediate for thermoelectric conversion modules according to any of the above (1) to (4), wherein the substrate is a glass substrate.
(6) The method for producing an intermediate for thermoelectric conversion modules according to any of the above (1) to (5), wherein the thermoelectric semiconductor composition contains a thermoelectric semiconductor material and the thermoelectric semiconductor material is a bismuth-tellurium-based thermoelectric semiconductor material, a telluride-based thermoelectric semiconductor material, an antimony-tellurium-based thermoelectric semiconductor material, or a bismuth-selenide-based thermoelectric semiconductor material.
(7) The method for producing an intermediate for thermoelectric conversion modules according to any of the above (1) to (6), wherein the thermoelectric semiconductor composition further contains a heat-resistant resin, and an ionic liquid and/or an inorganic ionic compound.
(8) The method for producing an intermediate for thermoelectric conversion modules according to any of the above (1) to (7), wherein the heat-resistant resin is a polyimide resin, a polyamide resin, a polyamideimide resin or an epoxy resin.
(9) The method for producing an intermediate for thermoelectric conversion modules according to any of the above (1) to (8), wherein the annealing temperature is 250 to 600° C.

### Advantageous Effects of Invention

According to the present invention, there is provided a method for producing an intermediate for thermoelectric conversion modules which does not require a supporting substrate, which enables annealing treatment of a thermoelectric semiconductor material in a form not having a joint to an electrode, and which enables annealing of a thermoelectric semiconductor material at an optimum annealing temperature.

### BRIEF DESCRIPTION OF DRAWINGS

FIG. 1 is an explanatory view of showing step-by-step an example of a process according to a production method for an intermediate for thermoelectric conversion modules of the present invention that contains a P-type thermoelectric element layer and an N-type thermoelectric element layer of a thermoelectric semiconductor composition.

FIG. 2 is a cross-sectional view for explaining an embodiment of a thermoelectric conversion module that uses an intermediate for thermoelectric conversion modules.

### DESCRIPTION OF EMBODIMENTS

### [Production Method for Intermediate for Thermoelectric Conversion Modules]

The production method for an intermediate for thermoelectric conversion modules of the present invention is a method for producing an intermediate for thermoelectric conversion modules that contains a P-type thermoelectric element layer and an N-type thermoelectric element layer of a thermoelectric semiconductor composition, and the method includes (A) a step of forming the P-type thermoelectric element layer and the N-type thermoelectric element layer on a substrate, (B) a step of annealing the P-type thermoelectric element layer and the N-type thermoelectric element layer formed in the step (A), (C) a step of forming a sealant layer containing a curable resin or a cured product thereof, on the P-type thermoelectric element layer and the N-type thermoelectric element layer annealed in the step (B), and (D) a step of peeling the P-type thermoelectric element layer and the N-type thermoelectric element layer and also the sealant layer formed in the steps (B) and (C) from the substrate.

In the production method for an intermediate for thermoelectric conversion modules of the present invention, after a P-type thermoelectric conversion layer and an N-type thermoelectric conversion layer are formed, for example, on a substrate having a high heatproof temperature such as glass, an annealing temperature independently optimum for the thermoelectric element layers of the P-type thermoelectric conversion layer and an N-type thermoelectric conversion layer is applicable to the layers, and consequently, the thermoelectric element layers can exhibit maximally the thermoelectric performance intrinsic to the individual thermoelectric element layers.

At the same time, a sealant layer that contains a curable resin (hereinafter this may be referred to as “thermosetting sealant sheet”) is formed on the annealed P-type thermoelectric conversion layer and N-type thermoelectric conversion layer, and these are integrally peeled from the substrate, and accordingly, the P-type thermoelectric conversion layer and the N-type thermoelectric conversion layer after annealed can be transferred to the sealant layer, and as a result, a substrate to be a supporting substrate that is a member to constitute an intermediate for thermoelectric conversion modules, and eventually a thermoelectric conversion module itself becomes unnecessary, therefore bringing into thickness reduction and weight reduction of modules and even cost reduction for production materials.

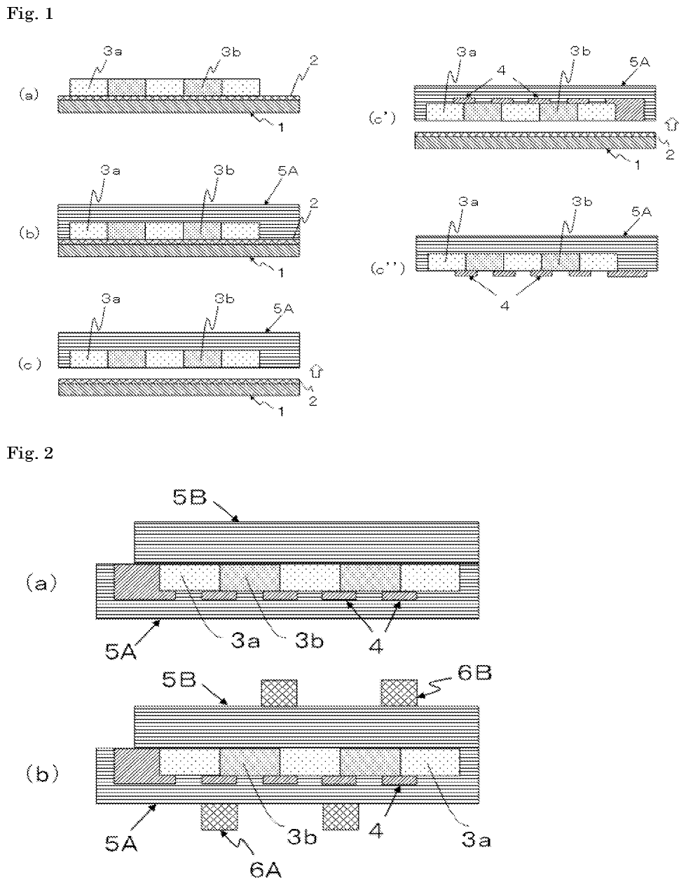

FIG. 1 is an explanatory view of showing step-by-step an example of a process according to a production method for an intermediate for thermoelectric conversion modules of the present invention that contains a P-type thermoelectric element layer and an N-type thermoelectric element layer of a thermoelectric semiconductor composition, in which (a) is a cross-sectional view after forming a sacrificial layer 2 on a substrate 1 followed by forming an N-type thermoelectric element layer 3a and a P-type thermoelectric element layer 3b, (b) is a cross-sectional view after forming a thermosetting resin-containing sealant layer 5A on the surface of the N-type thermoelectric element layer 3a and the P-type thermoelectric element layer 3b formed in (a), and (c) is a cross-sectional view after peeling the N-type thermoelectric element layer 3a and the P-type thermoelectric element layer 3b from the substrate 1 via the sacrificial layer 2 to transfer the N-type thermoelectric element layer 3a and the P-type thermoelectric element layer 3b onto a sealant layer 5A to form an intermediate for thermoelectric conversion modules (basic constitution of an intermediate for thermoelectric conversion modules).

(c′) is a cross-sectional view showing one example of an intermediate for thermoelectric conversion modules after a step of forming an electrode 4 on a joint between the N-type thermoelectric element layer 3a and the P-type thermoelectric element layer 3b in the constitution of (a).

(c″) is a cross-sectional view showing another example of an intermediate for thermoelectric conversion modules after forming an electrode 4 on an exposed joint between the N-type thermoelectric element layer 3a and the P-type thermoelectric element layer 3b of an intermediate for thermoelectric conversion modules obtained in (c).

### (A) Thermoelectric Element Layer Forming Step

The production method for an intermediate for thermoelectric conversion modules of the present invention incudes a thermoelectric element layer forming step.

The thermoelectric element layer forming step is a step of forming a thermoelectric element layer on a substrate, and is, for example, a step of forming an N-type thermoelectric element layer 3a and a P-type thermoelectric element layer 3b on a substrate 1 in FIG. 1(a) mentioned above.

The thermoelectric element layer (hereinafter this may be referred to as “thin film of a thermoelectric element layer”) in the present invention is formed of a thermoelectric semiconductor composition containing a thermoelectric semiconductor material. From the viewpoint of the shape stability of the thermoelectric element layer, preferably, the thermoelectric semiconductor material contains a heat-resistant resin, and from the viewpoint of thermoelectric performance, the layer is formed of a thermoelectric semiconductor composition containing a thermoelectric semiconductor material (hereinafter this may be referred to as “thermoelectric semiconductor fine particles”), a heat-resistant resin, and an ionic liquid and/or an inorganic ionic compound.

### (Thermoelectric Semiconductor Material)

The thermoelectric semiconductor material for use in the present invention, namely the thermoelectric semiconductor material to be contained in the P-type thermoelectric element layer and the N-type thermoelectric element layer is not specifically limited so far as the material is one capable of generating a thermoelectric force when given a temperature difference, and examples thereof include a bismuth-tellurium-based thermoelectric semiconductor material such as a P-type bismuth telluride, and an N-type bismuth telluride; a telluride-based thermoelectric semiconductor material such as GeTe and PbTe; an antimony-tellurium-based thermoelectric semiconductor material; a zinc-antinomy-based thermoelectric semiconductor material such as ZnSb, Zn₃Sb₂, and Zn₄Sb₃; a silicon-germanium-based thermoelectric semiconductor material such as SiGe; a bismuth-selenide-based thermoelectric semiconductor material such as Bi₂Se₃; a silicide-based thermoelectric semiconductor material such as β-FeSi₂, CrSi₂, MnSi_{1.73}, and Mg₂Si; an oxide-based thermoelectric semiconductor material; a Heusler material such as FeVAl, FeVAlSi, and FeVTiAl; and a sulfide-based thermoelectric semiconductor material such as TiS₂.

Among these, a bismuth-tellurium-based thermoelectric semiconductor material, a telluride-based thermoelectric semiconductor material, an antimony-tellurium-based thermoelectric semiconductor material or a bismuth-selenide-based thermoelectric semiconductor material is preferred.

Further, from the viewpoint of thermoelectric performance, a bismuth-tellurium-based thermoelectric semiconductor material such as a P-type bismuth telluride or an N-type bismuth telluride is more preferred.

The carrier of the P-type bismuth telluride is a hole and the Seebeck coefficient thereof is positive, for which, for example, preferably used is one represented by Bi_{X}Te₃Sb_{2-X}. In this case, X preferably satisfies 0<X≤0.8, more preferably 0.4≤X≤0.6. X being more than 0 and 0.8 or less is preferred since the Seebeck coefficient and the electrical conductivity of the material are large and the material can maintain the characteristics of a P-type thermoelectric element.

The carrier of the N-type bismuth telluride is an electron and the Seebeck coefficient thereof is negative, for which, for example, preferably used is one represented by Bi₂Te_{3-Y}Se_{Y}. In this case, Y is preferably 0≤Y≤3 (when Y=0, Bi₂Te₃), more preferably 0<Y≤2.7. Y being 0 or more and 3 or less is preferred since the Seebeck coefficient and the electrical conductivity of the material are large and the material can maintain the characteristics of an N-type thermoelectric element.

The thermoelectric semiconductor fine particles for use in the thermoelectric semiconductor composition are those prepared by grinding the above-mentioned thermoelectric semiconductor material to have a predetermined size using a fine powdering device or the like.

The blending amount of the thermoelectric semiconductor fine particles in the thermoelectric semiconductor composition is preferably 30 to 99% by mass. The amount is more preferably 50 to 96% by mass, even more preferably 70 to 95% by mass. The blending amount of the thermoelectric semiconductor fine particles falling within the above range is preferred since the Seebeck coefficient (absolute value of Peltier coefficient) is large, the electrical conductivity reduction can be prevented, only the thermal conductivity is lowered, and therefore the composition exhibits high-level thermoelectric performance and can form a film having a sufficient film strength and flexibility.

The average particle size of the thermoelectric semiconductor fine particles is preferably 10 nm to 200 μm, more preferably 10 nm to 30 μm, even more preferably 50 nm to 10 μm, and especially preferably 1 to 6 μm. Falling within the range, uniform dispersion is easy and electrical conductivity can be increased.

The method of producing the thermoelectric semiconductor fine particles by finely grinding the thermoelectric semiconductor material is not specifically defined, and the material may be ground into a predetermined size, using a known fine grinding mill or the like, such as a jet mill, a ball mill, a bead mill, a colloid mill, or a roller mill.

The average particle size of the thermoelectric semiconductor fine particles may be measured with a laser diffraction particle sizer (Master Sizer 3000 from Malvern Corporation), and the median value of the particle size distribution is taken as the average particle size.

Preferably, the thermoelectric semiconductor fine particles are previously heat-treated. (“Heat treatment” as referred to herein differs from the “annealing treatment” to be carried out in the annealing step in the present invention.) The heat treatment increases the crystallinity of the thermoelectric semiconductor fine particles and further increases the Seebeck coefficient or the Peltier coefficient of the thermoelectric conversion material since the surface oxide film of the thermoelectric semiconductor fine particles could be removed, therefore further increasing the figure of merit thereof. Not specifically defined, the heat treatment is preferably carried out, before preparing the thermoelectric semiconductor composition, in an inert gas atmosphere such as nitrogen or argon in which the gas flow rate is controlled or in a reducing gas atmosphere such as hydrogen in which also the gas flow rate is controlled, or in a vacuum condition, and is more preferably carried out in a mixed gas atmosphere of an inert gas and a reducing gas so as not to adversely affect the thermoelectric semiconductor fine particles. Specific temperature conditions depend on the thermoelectric semiconductor fine particles to be used, but in general, it is desirable that the treatment is carried out at a temperature not higher than the melting point of the fine particles but falling between 100 and 1,500° C., for a few minutes to several tens hours.

### (Heat-Resistant Resin)

In the thermoelectric semiconductor composition for use in the present invention, a heat-resistant resin is preferably used from the viewpoint that the thermoelectric semiconductor material is annealed at a high temperature. The heat-resistant resin acts as a binder between the thermoelectric semiconductor material (thermoelectric semiconductor fine particles) and enhances the flexibility of the thermoelectric conversion module, and in addition, the resin can facilitate formation of a thin film by coating. The heat-resistant resin is not specifically defined but is preferably one that can maintain various physical properties thereof such as mechanical strength and thermal conductivity thereof as a resin without losing them in crystal growth of the thermoelectric semiconductor fine particles through annealing treatment of the thin film of the thermoelectric semiconductor composition.

The heat-resistant resin is preferably a polyamide resin, a polyamideimide resin, a polyimide resin or an epoxy resin from the viewpoint that the heat resistance thereof is higher and that the resin has no negative influence on the crystal growth of the thermoelectric semiconductor fine particles in the thin film, and is more preferably a polyamide resin, a polyamideimide resin or a polyimide resin from the viewpoint of excellent flexibility thereof. In the case where a polyimide film is used as the substrate, the heat-resistant resin is more preferably a polyimide resin from the viewpoint of adhesiveness thereof to the polyimide film. In the present invention, polyimide resin is a generic term for polyimide and its precursors.

Preferably, the decomposition temperature of the heat-resistant resin is 300° C. or higher. When the decomposition temperature falls within the above range, the resin does not lose the function thereof as a binder and can maintain flexibility even when the thin film of the thermoelectric semiconductor composition is annealed, as described below.

Preferably, the mass reduction ratio in the heat-resistant resin at 300° C. in thermogravimetry (TG) is 10% or less, more preferably 5% or less, even more preferably 1% or less. When the mass reduction ratio falls within the above range, the resin does not lose the function thereof as a binder and can maintain the flexibility of the thermoelectric element layer even when the thin film of the thermoelectric semiconductor composition is annealed, as described below.

The blending amount of the heat-resistant resin in the thermoelectric semiconductor composition is preferably 0.1 to 40% by mass, more preferably 0.5 to 20% by mass, even more preferably 1 to 20% by mass, still more preferably 2 to 15% by mass. When the blending amount of the heat-resistant resin falls within the above range, the thermoelectric semiconductor material functions as a binder, and facilitates formation of a thin film to give a film satisfying both high-level thermoelectric performance and a high film strength.

### (Ionic Liquid)

The ionic liquid for use in the present invention is a molten salt of a combination of a cation and an anion, which can exist as a liquid in a broad temperature range of −50 to 500° C. The ionic liquid is characterized in that it has an extremely low vapor pressure and is nonvolatile, has excellent thermal stability and electrochemical stability, has a low viscosity and has a high ionic conductivity, and therefore, serving as a conductive assistant, the ionic liquid can effectively prevent reduction in the electrical conductivity between thermoelectric semiconductor fine particles. In addition, the ionic liquid has high polarity based on the aprotic ionic structure thereof, and is excellent in compatibility with the heat-resistance resin, and therefore can make the thermoelectric element layer have a uniform electrical conductivity.

The ionic liquid for use herein may be a known one or a commercially-available one. Examples thereof include those composed of a cation component of a nitrogen-containing cyclic cation compound such as pyridinium, pyrimidinium, pyrazolium, pyrrolidinium, piperidinium or imidazolium, or a derivative thereof, an amine-type cation such as tetraalkylammonium, or a derivative thereof, a phosphine-type cation such as phosphonium, trialkyl sulfonium or tetraalkyl phosphonium, or a derivative thereof, or a lithium cation or a derivative thereof, and an anion component of a chloride ion such as Cl⁻, AlCl₄⁻, Al₂Cl₇⁻ or ClO₄⁻, a bromide ion such as Br⁻, an iodide ion such as I⁻, a fluoride ion such as BF₄⁻ or PF₆⁻, a halide anion such as F(HF)n⁻, or any other anion component such as NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)n⁻, (CN)₂N⁻, C₄F₉SO₃⁻, (C₂F₅SO₂)₂N⁻, C₃F₇COO⁻, or (CF₃SO₂)(CF₃CO)N⁻.

Among the above-mentioned ionic liquids, it is preferable that, from the viewpoint of enhancing high-temperature stability and compatibility between thermoelectric semiconductor fine particles and resin, and preventing reduction in the electrical conductivity between thermoelectric semiconductor fine particles, the cation component in the ionic liquid contains at least one selected from a pyridinium cation and a derivative thereof, and an imidazolium cation and a derivative thereof. It is also preferable that the anion component of the ionic liquid contains a halide anion, more preferably at least one selected from Cl⁻, Br⁻ and I⁻.

Specific examples of the ionic liquid in which the cation component contains a pyridinium cation or a derivative thereof include 4-methyl-butylpyridinium chloride, 3-methyl-butylpyridinium chloride, 4-methyl-hexylpyridinium chloride, 3-methyl-hexylpyridinium chloride, 4-methyl-octylpyridinium chloride, 3-methyl-octylpyridinium chloride, 3,4-dimethyl-butylpyridinium chloride, 3,5-dimethyl-butylpyridinium chloride, 4-methyl-butylpyridinium tetrafluoroborate, 4-methyl-butylpyridinium hexafluorophosphate, 1-butyl-4-methylpyridinium bromide, 1-butyl-4-methylpyridinium hexafluorophosphate, and 1-butyl-4-methylpyridinium iodide. Among these, 1-butyl-4-methylpyridinium bromide, 1-butyl-4-methylpyridinium hexafluorophosphate and 1-butyl-4-methylpyridinium iodide are preferred.

Specific examples of the ionic liquid in which the cation component contains an imidazolium cation or a derivative thereof include [1-butyl-3-(2-hydroxyethyl)imidazolium bromide], [1-butyl-3-(2-hydroxyethyl)imidazolium tetrafluoroborate], 1-ethyl-3-methylimidazolium chloride, 1-ethyl-3-methylimidazolium bromide, 1-butyl-3-methylimidazolium chloride, 1-hexyl-3-methylimidazolium chloride, 1-octyl-3-methylimidazolium chloride, 1-decyl- 3-methylimidazolium chloride, 1-decyl-3-methylimidazolium bromide, 1-dodecyl-3-methylimidazolium chloride, 1-tetradecyl-3-methylimidazolium chloride, 1-ethyl-3-methylimidazolium tetrafluoroborate, 1-butyl-3-methylimidazolium tetrafluoroborate, 1-hexyl-3-methylimidazolium tetrafluoroborate, 1-ethyl-3-methylimidazolium hexafluorophosphate, 1-butyl-3-methylimidazolium hexafluorophosphate, 1-methyl-3-butylimidazolium methylsulfate, and 1,3-dibutylimidazolium methylsulfate. Among these, [1-butyl-3-(2-hydroxyethyl)imidazolium bromide] and [1-butyl-3-(2-hydroxyethyl)imidazolium tetrafluoroborate] are preferred.

Preferably, the ionic liquid has an electrical conductivity of 10⁻⁷ S/cm or more, more preferably 10⁻⁶ S/cm or more. When the electrical conductivity falls within the above range, the ionic liquid can effectively prevent reduction in the electrical conductivity between thermoelectric semiconductor fine particles, serving as a conductive assistant.

Also preferably, the decomposition temperature of the ionic liquid is 300° C. or higher. When the decomposition temperature falls within the above range, the ionic liquid can still maintain the effect thereof as a conductive assistant even when the thin film of the thermoelectric semiconductor composition is annealed, as described below.

Preferably, the mass reduction ratio in the ionic liquid at 300° C. in thermogravimetry (TG) is 10% or less, more preferably 5% or less, even more preferably 1% or less. When the mass reduction ratio falls within the above range, the ionic liquid can still maintain the effect thereof as a conductive assistant even when the thin film of the thermoelectric semiconductor composition is annealed, as described below.

The blending amount of the ionic liquid in the thermoelectric semiconductor composition is preferably 0.01 to 50% by mass, more preferably 0.5 to 30% by mass, even more preferably 1.0 to 20% by mass. The blending amount of the ionic liquid falling within the above range provides a film capable of effectively preventing electrical conductivity reduction and having high thermoelectric performance.

### (Inorganic Ionic Compound)

The inorganic ionic compound for use in the present invention is a compound composed of at least a cation and an anion. The inorganic ionic compound is solid at room temperature and has a melting point at any temperature falling within a temperature range of 400 to 900° C. and is characterized by having a high ionic conductivity, and therefore, serving as a conductive assistant, the compound can prevent reduction in the electrical conductivity between thermoelectric semiconductor fine particles.

A metal cation is used as the cation.

Examples of the metal cation include an alkali metal cation, an alkaline earth metal cation, a typical metal cation and a transition metal cation, and an alkali metal cation or an alkaline earth metal cation is more preferred.

Examples of the alkali metal cation include Li⁺, Na⁺, K⁺, Rb⁺, Cs⁺ and Fr⁺.

Examples of the alkaline earth metal cation include Mg²⁺, Ca²⁺, Sr²⁺ and Ba²⁺.

Examples of the anion include F⁻, Cl⁻, Br⁻, I⁻, OH⁻, CN⁻, NO₃⁻, NO₂⁻, ClO⁻, ClO₂⁻, ClO₃⁻, ClO₄⁻, CrO₄²⁻, HSO₄⁻, SCN⁻, BF₄⁻, and PF₆⁻.

As the inorganic ionic compound, known or commercially-available ones can be used. Examples thereof include those composed of a cation component such as a potassium cation, a sodium cation or a lithium cation, and an anion component, e.g., a chloride ion such as Cl⁻, AlCl₄⁻, Al₂Cl₇⁻, or ClO₄⁻, a bromide ion such as Br⁻, an iodide ion such as I⁻, a fluoride ion such as BF₄⁻ or PF₆⁻, a halide anion such as F(HF)ₙ⁻, or any other anion component such as NO₃⁻, OH⁻, or CN⁻.

Among the above-mentioned inorganic ionic compounds, those having at least one selected from potassium, sodium and lithium as the cation component are preferred from the viewpoint of securing high-temperature stability and compatibility between thermoelectric semiconductor fine particles and resin, and from the viewpoint of preventing reduction in the electrical conductivity between thermoelectric semiconductor fine particles. Also preferably, the anion component of the inorganic ionic compound contains a halide anion, more preferably at least one selected from Cl⁻, Br⁻ and I⁻.

Specific examples of the inorganic ionic compound having a potassium cation as the cation component include KBr, KI, KCl, KF, KOH, and K₂CO₃. Among these, KBr and KI are preferred.

Specific examples of the inorganic ionic compound having a sodium cation as the cation component include NaBr, NaI, NaOH, NaF, and Na₂CO₃. Among these, NaBr and NaI are preferred.

Specific examples of the inorganic ionic compound having a lithium cation as the cation component include LiF, LiOH, and LiNO₃. Among these, LiF and LiOH are preferred.

Preferably, the above inorganic ionic compound has an electrical conductivity of 10⁻⁷ S/cm or more, more preferably 10⁻⁶ S/cm or more. When the electrical conductivity falls within the above range, the inorganic ionic compound serving as a conductive assistant can effectively prevent reduction in the electrical conductivity between the thermoelectric semiconductor fine particles.

Also preferably, the decomposition temperature of the inorganic ionic compound is 400° C. or higher. When the decomposition temperature falls within the above range, the inorganic ionic compound can still maintain the effect thereof as a conductive assistant even when the thin film of the thermoelectric semiconductor composition is annealed, as described below.

Preferably, the mass reduction ratio in the inorganic ionic compound at 400° C. in thermogravimetry (TG) is 10% or less, more preferably 5% or less, even more preferably 1% or less. When the mass reduction ratio falls within the above range, the ionic liquid can still maintain the effect thereof as a conductive assistant even when the thin film of the thermoelectric semiconductor composition is annealed, as described below.

The blending amount of the inorganic ionic compound in the thermoelectric semiconductor composition is preferably 0.01 to 50% by mass, more preferably 0.5 to 30% by mass, even more preferably 1.0 to 10% by mass. When the blending amount of the inorganic ionic compound falls within the above range, the electrical conductivity can be effectively prevented from lowering and, as a result, a film having an improved thermoelectric performance can be realized.

In the case where the inorganic ionic compound and the ionic liquid are used together, the total content of the inorganic ionic compound and the ionic liquid in the thermoelectric semiconductor composition is preferably 0.01 to 50% by mass, more preferably 0.5 to 30% by mass, even more preferably 1.0 to 10% by mass.

### (Other Additives)

Further, the thermoelectric semiconductor composition for use in the present invention may optionally contain other additives such as a dispersant, a film formation aid, a light stabilizer, an antioxidant, a tackifier, a plasticizer, a colorant, a resin stabilizer, a filler, a pigment, a conductive filler, a conductive polymer and a curing agent, in addition to the above-mentioned components. One alone or two or more kinds of these additives may be used either singly or as combined.

### (Method for Preparing Thermoelectric Semiconductor Composition)

The method for preparing the P-type and N-type thermoelectric semiconductor compositions for use in the present invention is not specifically defined. The thermoelectric semiconductor compositions may be prepared by mixing and dispersing the above-mentioned thermoelectric semiconductor fine particles, the above-mentioned heat-resistant resin, one or both of the above-mentioned ionic liquid and inorganic ionic compound, and optionally other additives and also a solvent added thereto, according to a known method using an ultrasonic homogenizer, a spiral mixer, a planetary mixer, a disperser, or a hybrid mixer.

Examples of the solvent include toluene, ethyl acetate, methyl ethyl ketone, alcohols, tetrahydrofuran, methylpyrrolidone, and ethyl cellosolve. One alone or two or more different types of these solvents may be used here either singly or as combined. The solid concentration of the thermoelectric semiconductor composition is not specifically defined so far as the composition may have a viscosity suitable for coating operation.

A thin film of the thermoelectric semiconductor composition may be formed by applying the thermoelectric semiconductor composition onto a substrate for use in the present invention or onto a sacrificial layer to be mentioned hereinafter, and drying it thereon. According to the formation method, a large-area thermoelectric element layer can be produced in a simplified manner at a low cost.

Not specifically limited, the method for sequentially applying the P-type and N-type thermoelectric semiconductor compositions on a substrate may be any known method, including a screen printing method, a flexographic printing method, a gravure printing method, a spin coating method, a clip coating method, a die coating method, a spray coating method, a bar coating method, or a doctor blade coating method. In the case where the coating film is pattern-like formed, preferably employed is screen printing, stencil printing or slot die coating that realizes patterning in a simplified manner using a screen having a desired pattern.

Next, the resultant coating film is dried to give a thin film. As the drying method, employable is any known drying method such as a hot air drying method, a hot roll drying method, or an IR radiation method. The heating temperature is generally 80 to 150° C., and the heating time is generally a few seconds to several tens of minutes though it varies depending on the heating method.

In the case where a solvent is used in preparing the thermoelectric semiconductor composition, the heating temperature is not specifically defined so far as it falls within a temperature range capable of drying the used solvent.

Not specifically limited, the thickness of the thin film of the thermoelectric semiconductor composition is, from the viewpoint of thermoelectric performance and film strength, preferably 100 nm to 1000 μm, more preferably 300 nm to 600 μm, even more preferably 5 to 400 μm.

### (Substrate)

The substrate for use in the present invention incudes glass, silicon, ceramics, metals or plastics. From the viewpoint of carrying out annealing at a high temperature, glass, silicon, ceramics and metals are preferred, and from the viewpoint of adhesiveness to a sacrificial layer, material cost and dimensional stability after heat treatment, use of glass, silicon or ceramics is more preferred.

The thickness of the substrate is, from the viewpoint of process and dimensional stability, preferably 100 to 1200 μm, more preferably 200 to 800 μm, even more preferably 400 to 700 μm.

### <Sacrificial Layer Forming Step>

Preferably, the production method for an intermediate for thermoelectric conversion modules of the present invention includes a sacrificial layer forming step.

The sacrificial layer forming step is a step of forming a sacrificial layer on a substrate, and, for example, in FIG. 1(a), this is a step of applying a resin or a release agent to a substrate 1 to form a sacrificial layer 2.

### (Sacrificial Layer)

Preferably, the production method for an intermediate for thermoelectric conversion modules of the present invention uses a sacrificial layer.

The sacrificial layer is used for forming a thermoelectric element layer as a self-supported film, and is arranged between a substrate and a thermoelectric element layer, and after annealing treatment to be mentioned below and further after formation of a sealant layer, this functions to peel the thermoelectric element layer.

The material to constitute the sacrificial layer may be any one that can disappear or can remain after annealing treatment and, as a result, has a function to peel the thermoelectric element layer without having no influence on the properties of the thermoelectric element layer, and is preferably a resin or a release agent having any of such functions.

### (Resin)

Not specifically limited, the resin to constitute the sacrificial layer for use in the present invention includes a thermoplastic resin and a curable resin. The thermoplastic resin includes acrylic resins such as polymethyl (meth)acrylate, polyethyl (meth)acrylate, and methyl (meth)acrylate-butyl (meth)acrylate copolymer, polyolefin resins such as polyethylene, polypropylene, and polymethylpentene, polycarbonate resins, thermoplastic polyester resins such as polyethylene terephthalate and polyethylene naphthalate, and polystyrene, acrylonitrile-styrene copolymer, polyvinyl acetate, ethylene-vinyl acetate copolymer, vinyl chloride, polyurethane, polyvinyl alcohol, polyvinyl pyrrolidone, and ethyl cellulose. Polymethyl (meth)acrylate means polymethyl acrylate or polymethyl methacrylate, and the same shall apply to (meth) in the others. The curable resin includes a thermosetting resin and a photocurable resin. The thermosetting resin includes an epoxy resin and a phenolic resin. The photocurable resin includes a photocurable acrylic resin, a photocurable urethane resin, and a photocurable epoxy resin.

Among these, from the viewpoint that a thermoelectric element layer can be formed on the sacrificial layer and that the thermoelectric element layer can be readily peeled as a self-supported film even after annealing treatment at a high temperature, a thermoplastic resin is preferred, and polymethyl methacrylate, polystyrene, polyvinyl alcohol, polyvinyl pyrrolidone and ethyl cellulose are preferred, and from the viewpoint of material cost, peelability and the ability to maintain properties of thermoelectric element layer, polymethyl methacrylate and polystyrene are more preferred.

Also preferably, the mass reduction ratio of the resin in thermogravimetry (TG) at the annealing temperature to be mentioned below is 90% or more, more preferably 95% or more, even more preferably 99% or more. When the mass reduction ratio falls within the above range, the resin does not lose the function to peel a thermoelectric element layer even when the thermoelectric element layer is annealed, as mentioned below.

### (Release Agent)

Not specifically limited, the release agent to constitute the sacrificial layer for use in the present invention includes a fluorine-based release agent (fluorine atom-containing compound, for example, polytetrafluoroethylene), a silicone-based release agent (silicone compound, for example, silicone resin, polyoxyalkylene unit-having polyorganosiloxane), a higher fatty acid or a salt thereof (for example, metal salt), a higher fatty acid ester, and a higher fatty acid amide.

Among these, from the viewpoint that a thermoelectric element layer can be formed on the sacrificial layer and thermoelectric conversion material chips can be readily peeled (released) as self-supported films even after annealing treatment at a high temperature, a fluorine-based release agent and a silicone-based release agent are preferred, and from the viewpoint of material cost, releasability and the ability to maintain properties of thermoelectric conversion material, a fluorine-based release agent is more preferred.

The thickness of the sacrificial layer is preferably 10 nm to 10 μm, more preferably 50 nm to 5 μm, even more preferably 200 nm to 2 μm. The sacrificial layer whose thickness falls within the range facilitates peeling after annealing treatment and can readily maintain the thermoelectric performance of the thermoelectric element layer after peeled.

In particular, in the case where a resin is used, the thickness of the sacrificial layer is preferably 50 nm to 10 μm, more preferably 100 nm to 5 μm, even more preferably 200 nm to 2 μm. The sacrificial layer of resin that has a thickness falling within the range facilitates peeling after annealing treatment and can readily maintain the thermoelectric performance of the thermoelectric element layer after peeled. Further, even in the case where any other layer is further laminated on the sacrificial layer, the self-supported film can be maintained as such.

Similarly, in the case where a release agent is used, the thickness of the sacrificial layer is preferably 10 nm to 5 μm, more preferably 50 nm to 1 μm, even more preferably 100 nm to 0.5 μm, especially more preferably 200 nm to 0.1 μm. The sacrificial layer using a release agent that has a thickness falling within the range facilitates peeling after annealing treatment and can readily maintain the thermoelectric performance of the thermoelectric element layer after peeled.

The sacrificial layer is formed using the above-mentioned resin or release agent.

The method for forming the sacrificial layer includes various coating methods on a substrate, such as a clip coating method, a spin coating method, a spray coating method, a gravure coating method, a die coating method, and a doctor blade coating method. The method is appropriately selected depending on the properties of the resin or the release agent used.

### (B) Annealing Step

The production method for an intermediate for thermoelectric conversion modules of the present invention includes an annealing step.

The annealing step is a step of heat-treating a thermoelectric element layer formed on the sacrificial layer on a substrate, at a predetermined temperature, and, for example, in FIG. 1(a), this is a step of annealing the N-type thermoelectric element layer 3a and the P-type thermoelectric element layer 3b on the sacrificial layer 2.

In the present invention, the annealing treatment can stabilize thermoelectric performance and can promote crystal growth in the thermoelectric semiconductor material (fine particles) in the thermoelectric element layer, and can thereby further enhance thermoelectric performance.

Generally, the annealing treatment is carried out in an inert gas atmosphere of nitrogen or argon or in a reducing gas atmosphere in which the gas flow rate is controlled, or in vacuum, and depending on the heatproof temperature of the heat-resistant resin, the ionic liquid and the inorganic ionic compound used and also on that of the resin and the release agent used for the sacrificial layer, the annealing temperature is generally 100 to 600° C. and the annealing time is a few minutes to several tens of hours, preferably at 150 to 600° C. and for a few minutes to several tens of hours, more preferably at 250 to 600° C. and for a few minutes to several tens of hours, even more preferably at 300 to 550° C. and for a few minutes to several tens of hours.

The optimum annealing temperature and processing time may vary depending on the thermoelectric semiconductor material used, and in such a case, the formed P-type thermoelectric element layer and N-type thermoelectric element layer can be separately annealed under different optimum conditions for them. Such is more preferred since the resultant thermoelectric element layers can be made to sufficiently exhibit their own intrinsic thermoelectric performance. In the case, the thermoelectric element layers are formed and annealed in the order of the thermoelectric semiconductor materials having a higher optimum annealing temperature.

### <Electrode Forming Step>

Preferably, the production method for an intermediate for thermoelectric conversion modules of the present invention includes a step of forming an electrode for securing good electric connection between the P-type thermoelectric element layer and the N-type thermoelectric element layer.

The electrode forming step is preferably a step of forming a predetermined electrode in a lower part or an upper part of a joint between the annealed P-type thermoelectric element layer and N-type thermoelectric element layer.

### (Electrode)

The metal material for the electrode of thermoelectric conversion modules for use in the present invention includes copper, gold, nickel, aluminum, rhodium, platinum, chromium, palladium, stainless steel, molybdenum and an alloy containing any of these metals.

The thickness of the electrode layer is preferably 10 nm to 200 μm, more preferably 30 nm to 150 μm, even more preferably 50 nm to 120 μm. When the thickness of the electrode layer falls within the range, the electrical conductivity thereof can be high and the resistance can be low and the electrode can have a sufficient strength.

The electrode is formed using the above-mentioned metal material.

As a method for forming the electrode, employable is a method that includes forming an unpatterned electrode on a resin film followed by patterning electrode to have a predetermined pattern by known physical treatment or chemical treatment or a combination thereof mainly based on photolithography, or a method of directly forming a patterned electrode according to a screen printing method, or an inkjet method.

The method for forming an unpatterned electrode includes a dry process of PVD (physical vapor deposition) such as a vacuum evaporation method, a sputtering method, or an ion-plating method, or CVD (chemical vapor deposition) such as thermal CVD or atomic layer deposition (ALD), or a wet process of various coating or electrodeposition methods such as a dip coating method, a spin coating method, a spray coating method, a gravure coating method, a die coating method or a doctor blade method, as well as a silver salt method, an electrolytic plating method, an electroless plating method, or lamination of metal foils; and the method may be appropriately selected depending on the material of the electrode.

The electrode for use in the present invention is required to have high electrical conductivity and high thermal conductivity from the viewpoint of maintaining thermoelectric performance, and therefore an electrode of a film formed according to a plating method or a vacuum film formation method is preferably used. As readily realizing a high electrical conductivity and a high thermal conductivity, preferred is an electrode formed according to a vacuum film formation method such as a vacuum deposition method or a sputtering method, as well as by an electrolytic plating method or an electroless plating method. Depending on the requirement for the dimension of the pattern to be formed and the dimensional accuracy thereof, a pattern may be formed with ease via a hard mask such as a metal mask.

The thickness of the layer of the metal material is preferably 10 nm to 200 μm, more preferably 30 nm to 150 μm, even more preferably 50 nm to 120 μm. When the thickness of the layer of the metal material falls within the range, the layer can have a high electric conductivity and a low resistance, and can have a sufficient strength as an electrode.

### (C) Sealant Layer Forming Step

The production method for an intermediate for thermoelectric conversion modules of the present invention includes a sealant layer forming step.

In one embodiment of the present invention, the step is for forming a sealant layer on the surface of the annealed thermoelectric element layer and, for example, in FIG. 1(a), this is a step of forming a sealant layer 5A on the N-type thermoelectric element layer 3a and the P-type thermoelectric element layer 3b.

The sealant layer may be laminated on the thermoelectric element layer either directly or via any other layer, and may be laminated thereon via a gas barrier layer to be mentioned below or via an insulating layer for insulation of the thermoelectric element layer from a highly thermal conductive layer to constitute a thermoelectric conversion module to be mentioned below.

The sealant layer may be formed according to a known method. Briefly, the layer may be directly formed on a thermoelectric element layer, or apart from this, a sealant layer previously formed on a release sheet may be stuck to a thermoelectric element layer so as to be transferred to the thermoelectric element layer. Further apart from these, a sheet of a sealant layer is previously formed, or a sheet of a sealant layer having a highly thermal conductive layer to constitute a thermoelectric conversion module to be mentioned below is previously prepared, and the sheet is laminated on the surface of a thermoelectric element layer to form a sealant layer by thermal lamination.

### (Sealant Layer)

The sealant layer for use in the present invention is formed of a sealant composition containing a curable resin or a cured product thereof.

The sealant layer can support the thermoelectric element layer, and further can effectively prevent penetration of water vapor in air through the thermoelectric element layer to suppress degradation of the layer.

### <Curable Resin>

Not specifically limited, the curable resin for use in the present invention may be any ordinary resins used in the field of electronic parts, and may be appropriately selected from those resins Preferred are a thermosetting resin and an energy ray-curable resin.

In the present invention, when the sealant composition contains a thermosetting resin or an energy ray-curable resin, the layer of the composition can reduce water vapor penetration therethrough and can firmly seal up the thermoelectric element layer.

Not specifically limited, the thermosetting resin includes an epoxy resin, a phenolic resin, a melamine resin, a urea resin, a polyester resin, a urethane resin, an acrylic resin, a polyimide resin, a benzoxazine resin, a phenoxy resin, an acid anhydride compound, and an amine compound. One or more of these can be used either singly or as combined. Among these, use of an epoxy resin, a phenolic resin, a melamine resin, a urea resin, an acid anhydride compound or an amine compound is preferred as favorable for curing in the case of using an imidazole curing catalyst. Especially from the viewpoint of exhibiting excellent adhesiveness, preferred is use of an epoxy resin, a phenolic resin or a mixture thereof, or use of a mixture of an epoxy resin with at least one selected from the group consisting of a phenolic resin, a melamine resin, an urea resin, an amine compound and an acid anhydride compound.

An epoxy resin has a property to form, in general, a three-dimensional network structure when heated, thereby giving a hard cured product. As such an epoxy resin, various kinds of epoxy resins can be used. Specific examples thereof include a glycidyl ether of a phenol compound such as bisphenol A, bisphenol F, resorcinol, phenylnovolak, or cresolnovolak; a glycidyl ether of an alcohol compound such as butanediol, polyethylene glycol or polypropylene glycol; a glycidyl ether of a carboxylic acid such as phthalic acid, isophthalic acid, or tetrahydrophthalic acid; a glycidyl-type or alkylglycidyl-type epoxy resin in which an active hydrogen bonding to a nitrogen atom, such as aniline isocyanurate is substituted with glycidyl group; and a so-called alicyclic epoxide prepared by introducing an epoxy moiety, for example, by oxidation of a carbon-carbon double bond in the molecule, such as vinylcyclohexane diepoxide, 3,4-epoxycyclohexylmethyl-3,4-dicyclohexane-carboxylate, and 2-(3,4-epoxy)cyclohexyl-5,5-spiro(3,4-epoxy)cyclohexane-m-dioxane. In addition, an epoxy resin having a biphenyl skeleton, a triphenylmethane skeleton, a dicyclohexadiene skeleton or a naphthalene skeleton is also usable. One alone or two or more kinds of these epoxy resins can be used either singly or as combined. Among the above-mentioned epoxy resins, preferred is use of a bisphenol A glycidyl ether (bisphenol A-type epoxy resin), a biphenyl skeleton-having epoxy resin (biphenyl-type epoxy resin), a naphthalene skeleton-having epoxy resin (naphthalene-type epoxy resin) or a combination of these.

Examples of the phenol resin include bisphenol A, tetramethylbisphenol A, diallylbisphenol A, biphenol, bisphenol F, diallylbisphenol F, triphenylmethane-type phenol, tetrakisphenol, novolak-type phenol, cresol-novolak resin, and biphenylaralkyl skeleton-having phenol (biphenyl-type phenol), and among these, use of biphenyl-type phenol is preferred. One alone or two or more kinds of these phenol resins may be used either singly or as combined. In the case where an epoxy resin is used as a curable resin, preferred is combined use with a phenol resin from the viewpoint of reactivity with epoxy resin.

The energy ray-curable resin is not specifically limited, and examples thereof include a compound having one or more polymerizable unsaturated bonds such as an acrylate-type functional group-having compound. Examples of the compound having one polymerizable unsaturated bond include ethyl (meth)acrylate, ethylhexyl (meth)acrylate, styrene, methylstyrene, and N-vinylpyrrolidone. Examples of the compound having 2 or more polymerizable unsaturated bonds include polyfunctional compounds such as polymethylolpropane tri(meth)acrylate, hexanediol (meth)acrylate, tripropylene glycol di(meth)acrylate, diethylene glycol di(meth)acrylate, pentaerythritol tri(meth)acrylate, dipentaerythritol hexa(meth)acrylate, 1,6-hexanediol di(meth)acrylate, neopentyl glycol di(meth)acrylate, and modified products thereof, as well as reaction products of these polyfunctional compounds and (meth)acrylates (e.g., poly(meth)acrylate esters of polyalcohols). In this description, (meth)acrylate means methacrylate and acrylate.

In addition to the above-mentioned compounds, polyester resins, polyether resins, acrylic resins, epoxy resins, urethane resins, silicone resins and polybutadiene resins having polymerizable unsaturated bond and having a relatively low molecular weight are also usable as the above-mentioned energy ray-curable resin.

Among these, from the viewpoint of excellent heat resistance, high adhesion power and small water penetration rate, a polyolefin resin, an epoxy resin or an acrylic resin is preferred.

Preferably, a photopolymerization initiator is used along with the energy ray-curable resin. The photopolymerization initiator for use in the present invention is contained in the energy ray-curable resin-containing sealant composition, and therefore the energy ray-curable resin can be cured under UV rays. Examples of the photopolymerization initiator usable herein include benzoin, benzoin methyl ether, benzoin ethyl ether, benzoin isopropyl ether, benzoin n-butyl ether, benzoin isobutyl ether, acetophenone, dimethylaminoacetophenone, 1-hydroxy-cyclohexyl phenyl ketone, 2,2-dimethoxy-2-phenylacetophenone, 2,2-diethoxy-2-phenylacetophenone, 2-hydroxy-2-methyl-1-phenylpropan-1-one, 2-aminoanthraquinone, 2-methylthioxanthone, 2-ethylthioxanthone, 2-chlorothioxanthone, 2,4-dimethylthioxanthone, 2,4-diethylthioxanthone, benzyldimethyl ketal, acetophenone dimethyl ketal, and p-dimethylaminobenzoic acid esters.

One alone or two or more kinds of photopolymerization initiators may be used either singly or as combined. The amount thereof to be incorporated is selected generally within a range of 0.2 to 10 parts by mass relative to 100 parts by mass of the energy ray-curable resin.

The curable resin-containing sealant composition may optionally contain additives such as a crosslinking agent, a filler, a plasticizer, an antiaging agent, an antioxidant, a UV absorbent, a colorant such as pigment or dye, a tackifier, an antistatic agent and a coupling agent, within an appropriate range.

One or more sealant layers may be laminated. In the case where two or more sealant layers are laminated, they may be the same as or different from each other.

The thickness of the sealant layer is preferably 0.5 to 100 μm, more preferably 3 to 50 μm, even more preferably 5 to 30 μm. Within the range, when the layer is laminated on the surface of the thermoelectric element layer of the intermediate for thermoelectric conversion modules, the layer can suppress water vapor penetration therethrough to enhance the durability of the intermediate for thermoelectric conversion modules and also the thermoelectric conversion module using the intermediate for thermoelectric conversion modules to be mentioned below.

Further, as mentioned above, the thermoelectric element layer is preferably in direct contact with the sealant layer. As a result of direct contact between the thermoelectric element layer and the sealant layer, water vapor in air does not directly exist between the thermoelectric element layer and the sealant layer and therefore water vapor penetration in the thermoelectric element layer can be thereby suppressed and the sealing performance of the sealant layer can improve.

The content of the curable resin in the sealant composition is preferably 10 to 90% by mass, more preferably 20 to 80% by mass. When the content is 10% by mass or more, the sealant layer can cure more sufficiently to suppress water vapor penetration therethrough and, in addition, the layer can firmly seal up the thermoelectric element layer. When the content is 90% by mass or less, the storage stability of the sealant layer can be more excellent.

The sealant composition can contain a thermoplastic resin.

Containing a thermoplastic resin, moldability of the sealant composition can improve and deformation of the sealant layer owing to cure shrinkage of the curable resin contained in the layer can be prevented.

Examples of the thermoplastic resin include a phenoxy resin, an olefin resin, a polyester resin, a polyurethane resin, a polyester urethane resin, an acrylic resin, an amide resin, a styrene resin, a silane resin, and a rubber resin. One alone or two or more kinds of these can be used either singly or as combined.

The content of the thermoplastic resin in the sealant composition is preferably 10 to 90% by mass, more preferably 20 to 80% by mass. When the content is 10% by mass or more, moldability of the sealant layer can improve. When the content is 90% by mass or less, deformation owing to cure shrinkage can be prevented.

The sealant composition may contain a silane coupling agent.

Containing a silane coupling agent, the sealant composition can have a higher adhesion strength at room temperature and in a high-temperature environment.

The silane coupling agent is preferably an organic silicon compound having at least one alkoxysilyl group in the molecule.

The silane coupling agent includes polymerizable unsaturated group-containing silicon compounds such as vinyltrimethoxysilane, vinyltriethoxysilane, and methacryloxypropyltrimethoxysilane; epoxy structure-having silicon compounds such as 3-glycidoxypropyltrimethoxysilane, and 2-(3,4-epoxycyclohexyl)ethyltriethoxysilane; amino group-containing silicon compounds such as 3-aminopropyltrimethoxysilane, N-(2-aminoethyl)-3-aminopropyltrimethoxysilane, and N-(2-aminoethyl)-3-aminopropylmethyldimethoxysilane; and 3-chloropropyltrimethoxysilane; and 3-isocyanatopropyltriethoxysilane.

One alone or two or more kinds of these silane coupling agents may be used either singly or as combined.

In the case where the sealant composition contains a silane coupling agent, the content of the silane coupling agent is generally 0.01 to 3% by mass.

The sealant composition may contain a filler.

Containing a filler, the sealant composition may be given functions of high heat resistance and high thermal conductivity.

Examples of the filler include those formed of a material such as silica, alumina, glass, titanium oxide, aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, crystalline silica, amorphous silica, composite oxides such as mullite or cordierite, as well as montmorillonite or smectite. One alone or two or more kinds of these may be used either singly or as combined. The surface of the filler may be surface-treated.

The shape of the filler may be any of spherical, granular, acicular, tabular or amorphous ones.

The average particle size of the filler is generally 0.01 to 20 μm or so.

### <Gas Barrier Layer>

The intermediate of the present invention may further contain a gas barrier layer in addition to the sealant layer. The gas barrier layer can more effectively prevent penetration of water vapor in air.

The gas barrier layer may be directly laminated on the thermoelectric element layer, or may be formed of a layer containing the main ingredient to be mentioned below on a substrate, and any surface thereof may be directly laminated on the thermoelectric element layer, or may be laminated via a sealant layer or an insulation layer to be used for insulation of the highly thermal conductive layer to constitute the thermoelectric conversion module having conductivity to be mentioned below.

The gas barrier layer for use in the present invention contains, as a main ingredient, one or more selected from the group consisting of metals, inorganic compounds and polymer compounds.

As the substrate, a flexible one is used, and though not specifically limited, a resin film can be used.

The resin for the resin film includes polyimide, polyamide, polyamideimide, polyphenylene ether, polyether ketone, polyether ether ketone, polyolefin, polyester, polycarbonate, polysulfone, polyether sulfone, polyphenylene sulfide, polyarylate, nylon, acrylic resin, cycloolefin polymer, and aromatic polymer.

Among these, the polyester includes polyethylene terephthalate (PET), polybutylene terephthalate, polyethylene naphthalate (PEN), and polyarylate. The cycloolefin polymer incudes norbornene polymer, monocyclic olefin polymer, cyclic conjugated diene polymer, vinyl alicyclic hydrocarbon polymer, and hydrides thereof.

Among the resin for use in the resin film, from the viewpoint of cost and heat resistance, polyethylene terephthalate (PET), polyethylene naphthalate (PEN), and nylon are preferred.

The metal includes aluminum, magnesium, nickel, zinc, gold, silver, copper and tin, and preferably the metal is used as a vapor deposition film. Among these, from the viewpoint of productivity, cost and gas barrier performance, aluminum and nickel are preferred. One alone or two or more of these including alloys can be used either singly or as combined. The vapor deposition film may be formed according to an ordinary deposition method such as a vacuum evaporation method or an ion plating method, or may be formed according to any other method than the vapor deposition method, for example, a sputtering method such as a DC sputtering method or a magnetron sputtering method, or any other dry method such as a plasma CVD method. Since the metal vapor deposition film generally has conductivity, and is therefore laminated on the thermoelectric element layer via the above-mentioned substrate or the like.

The inorganic compound includes inorganic oxides (MOₓ), inorganic nitrides (MN_{y}), inorganic carbides (MC_{z}), inorganic oxycarbides (MOₓC_{z}), inorganic nitrocarbides (MN_{y}C_{z}), inorganic oxynitrides (MOₓN_{y}), and inorganic oxynitrocarbides (MOₓN_{y}C_{z}). Here, x, y and z each indicates the composition ratio of each compound. M represents a metal element such as silicon, zinc, aluminum, magnesium, indium, calcium, zirconium, titanium, boron, hafnium, or barium. M may be a single element or may be two or more elements. The inorganic compound includes oxides such as silicon oxide, zinc oxide, aluminum oxide, magnesium oxide, indium oxide, calcium oxide, zirconium oxide, titanium oxide, boron oxide, hafnium oxide, and barium oxide; nitrides such as silicon nitride, aluminum nitride, boron nitride, and magnesium nitride; carbides such as silicon carbide; and sulfides. Composites of two or more selected from these inorganic compounds (e.g., oxynitrides, oxycarbides, nitrocarbides, oxynitrocarbides) are also usable here. In addition, composites (including oxynitrides, oxycarbides, nitrocarbides, oxynitrocarbides) containing two or more kinds of metal elements such as SiOZn are also usable. Preferably, these are used as a vapor deposition film, but in the case where a vapor deposition film could not be formed, films formed of a different method such as a DC sputtering method, a magnetron sputtering method or a plasma CVD method are also usable.

M is preferably a metal element such as silicon, aluminum or titanium. In particular, an inorganic layer of silicon oxide where M is silicon has high-level gas barrier performance, and an inorganic layer of silicon nitride has further higher-level gas barrier performance. A composite of silicon oxide and silicon nitride (inorganic oxynitride (MOₓN_{y})) is especially preferred, and when the silicon nitride content therein is high, the gas barrier performance of the composite improves.

A vapor deposition film of an inorganic compound generally has insulation properties in many cases, but the present invention includes conductive films of zinc oxide or indium oxide. In this case, when the inorganic compound of the type is layered on a thermoelectric element layer, the compound is laminated via the above-mentioned substrate, or is used within a range not having any influence on the performance of the intermediate for thermoelectric conversion modules.

The polymer compound includes silicon-containing polymer compounds such as polyorganosiloxane and polysilazane compounds, as well as polyimides, polyamides, polyamideimides, polyphenylene ethers, polyether ketones, polyether ether ketones, polyolefins, and polyesters. One alone or two or more kinds of these polymer compounds may be used either singly or as combined.

Among these, silicon-containing polymer compounds are preferred as the polymer compound having gas barrier performance. The silicon-containing polymer compounds are preferably polysilazane compounds, polycarbosilane compounds, polysilane compounds, and polyorganosiloxane compounds. Among these, from the viewpoint of forming a barrier layer having excellent gas barrier performance, polysilazane compounds are more preferred.

A vapor deposition layer of an inorganic compound or a silicon oxynitride layer formed of a layer having oxygen, nitrogen and silicon as main constituent atoms, which is formed by modifying a polysilazane compound-containing layer, is preferably used from the viewpoint of having interlayer adhesiveness, gas barrier performance and flexibility.

For example, the gas barrier layer can be formed by treating a polysilazane compound-containing layer according to plasma ion injection treatment, plasma treatment, UV irradiation treatment or heat treatment. The ion to be injected in plasma ion injection treatment includes hydrogen, nitrogen, oxygen, argon, helium, neon, xenon and krypton.

Specific examples of plasma ion injection treatment include a method of injecting an ion that exists in plasma generated using an external electric field, into a polysilazane compound-containing layer, or a method of injecting an ion that exists in plasma generated only by an electric field of a negative high-voltage pulse to be imparted to a layer formed of a gas barrier layer forming material, into a polysilazane compound-containing layer.

Plasma treatment is a method of exposing a polysilazane compound-containing layer to plasma to thereby modify the layer that contains a silicon-containing polymer. For example, plasma treatment can be carried out according to the method described in JP 2012-106421 A. UV irradiation treatment is a method of irradiating a polysilazane compound-containing layer with UV rays to thereby modify the layer that contains a silicon-containing polymer. For Example, UV irradiation treatment can be carried out according to the method described in JP 2013-226757 A.

Among these, ion injection treatment is preferred since, according to the treatment, the polysilazane compound-containing layer can be efficiently modified even inside it without roughening the surface of the layer to thereby form a gas barrier layer having more excellent gas barrier performance.

The thickness of the layer that contains a metal, an inorganic compound and a polymer compound may vary depending on the compound to be used, but is generally 0.01 to 50 μm, preferably 0.03 to 10 μm, more preferably 0.05 to 0.8 μm, even more preferably 0.10 to 0.6 μm. When the thickness of the layer containing a metal, an inorganic compound or a resin falls within the range, the water vapor penetration can be effectively suppressed.

The thickness of the substrate-having gas barrier layer of a metal, an inorganic compound and a polymer compound is preferably 10 to 80 μm, more preferably 15 to 50 μm, even more preferably 20 to 40 μm. When the thickness of the gas barrier layer falls within the range, excellent gas barrier performance can be attained and, in addition, both flexibility and film strength can be satisfied.

The gas barrier layer may be one layer or may be a laminate of two or more layers. In the case where two or more layers are laminated, they may be the same as or different from each other.

### (D) Thermoelectric Element Layer Transfer Step

The production method for an intermediate for thermoelectric conversion modules of the present invention includes a step of peeling the thermoelectric element layer from the substrate and transferring the thermoelectric element layer to a sealant layer.

The thermoelectric element layer transfer step is a step of annealing the thermoelectric element layer and then transferring the thermoelectric element layer on the substrate or the sacrificial layer onto a sealant layer, and for example, as in FIG. 1(c), this is a step of peeling the N-type thermoelectric element layer 3a and the P-type thermoelectric element layer 3b from the substrate 1 via the sacrificial layer 2, and transferring the N-type thermoelectric element layer 3a and the P-type thermoelectric element layer 3b onto the sealant layer 5A.

The peeling method from the sacrificial layer is not specifically limited so far as the annealed thermoelectric element layer can be peeled from the sacrificial layer in a state that keeps the shape and the properties thereof, and may be any known method.

### [Production Method for Thermoelectric Conversion Module]

The production method for a thermoelectric conversion module is a production method using the intermediate for thermoelectric conversion modules of the present invention, and preferably incudes a step of forming a sealant layer and a step of forming a highly thermal conductive layer.

FIG. 2 is a cross-sectional configuration view showing an embodiment of a thermoelectric conversion module that uses an intermediate for thermoelectric conversion modules, in which (a) is a cross-sectional view of a thermoelectric conversion module after formation of a curable resin-containing sealant layer 5B on the exposed surfaces of the N-type thermoelectric element layer 3a and the P-type thermoelectric element layer 3b on the side opposite to the surface having the electrode 4 formed thereon of the intermediate for thermoelectric conversion modules of FIG. 1(c′), and (b) is a cross-sectional view of a thermoelectric conversion module having a highly thermal conductive layer 6A and a highly thermal conductive layer 6B arranged on both surfaces of the thermoelectric conversion module formed in (a).

### <Sealant Layer Forming Step>

The production method for thermoelectric conversion modules that uses the intermediate for thermoelectric conversion modules obtained according to the production method for an intermediate for thermoelectric conversion modules of the present invention preferably includes a sealant layer forming step. The sealant layer forming step is, for example, as in FIG. 2(a), a step of further forming a curable resin-containing sealant layer 5B on the exposed surfaces of the N-type thermoelectric element layer 3a and the P-type thermoelectric element layer 3b on the side opposite to the surface having the electrode 4 formed thereon of the intermediate for thermoelectric conversion modules.

The sealant layer forming method, the material to be used and the thickness of the layer are the same as those described in the section of the production method for an intermediate for thermoelectric conversion modules. The sealant layer may be laminated directly on the thermoelectric element layer of the intermediate for thermoelectric conversion modules, or may be laminated via any other layer, or may also be laminated via the above-mentioned gas barrier layer, or an insulation layer for insulation between the highly thermal conductive layer to be mentioned below and the thermoelectric element layer.

### <Highly Thermal Conductive Layer Forming Step>

The production method for thermoelectric conversion modules that uses the intermediate for thermoelectric conversion modules obtained according to the production method for an intermediate for thermoelectric conversion modules of the present invention preferably includes a highly thermal conductive layer forming step. The highly thermal conductive layer forming step is, for example, as in FIG. 2(b), a step of forming a highly thermal conductive layer 6A and a highly thermal conductive layer 6B in that order on the sealant layer 5A and the sealant layer 5B, respectively.

The highly thermal conductive layer is provided on one surface or both surfaces of a thermoelectric conversion module and functions as a radiation layer. From the viewpoint of thermoelectric performance, the highly thermal conductive layer is provided on both surfaces. In the present invention, for example, the thus-formed highly thermal conductive layer acts to efficiently give a sufficient temperature difference in the in-plane direction to the thermoelectric element layer inside the thermoelectric conversion module.

### (Highly Thermal Conductive Layer)

The highly thermal conductive layer is formed of a highly thermal conductive material. The highly thermal conductive material for use for the highly thermal conductive layer includes a simple metal such as copper, silver, iron, nickel, chromium and aluminum, and an alloy such as stainless and brass. Among these, preferred are copper (including oxygen-free copper), stainless and aluminum, and from the viewpoint of high thermal conductivity and easy workability, copper is more preferred.

Typical examples of the highly thermal conductive material for use in the present invention are shown below.

### Oxygen-Free Copper

OFC (oxygen-free copper) is a high-purity copper generally having a purity of 99.95% (3 N) or more and not containing an oxide. According to Japanese Industrial Standards, oxygen-free copper (JIS H 3100, C1020) and oxygen-free copper for electron tubes (JIS H 3510, C1011) are defined.

### Stainless (JIS)

SUS 304: 18Cr-8Ni (containing 18% Cr and 8% Ni)

SUS 316: 18Cr-12Ni (stainless steel containing 18% Cr, 12% Ni, and molybdenum (Mo))

The method for forming a highly thermal conductive layer is not specifically limited, and is, for example, a method of directly forming a pattern of a highly thermal conductive layer according to a screen printing method or an inkjet method.

Also employable herein is a method of patterning an unpatterned highly thermal conductive layer formed of a highly thermal conductive material, or a rolled metal foil or an electrolytic metal foil that is formed in a dry process such as PVD (physical vapor deposition), e.g., a vacuum evaporation method, a sputtering method or an ion plating method, or CVD (chemical vapor deposition), e.g., thermal CVD or atomic layer deposition (ALD), or in other various coating methods such as a dip coating method, a spin coating method, a spray coating method, a gravure coating method, a die coating method or a doctor coating method, or a wet process of electrodeposition or the like, as well as according to a silver salt method, an electrolytic plating method or an electroless plating method, according to known physical treatment of mainly photolithography or chemical treatment, or according to a combination of those treatments.

The thermal conductivity of the highly thermal conductive layer formed of a highly thermal conductive material for use in the present invention is preferably 5 to 500 W/(m·K), more preferably 8 to 500 W/(m·K), even more preferably 10 to 450 W/(m·K), further more preferably 12 to 420 W/(m·K), most preferably 15 to 400 W/(m·K). When the thermal conductivity falls within the range, the thermoelectric element layer can be efficiently given a temperature difference in the in-plane direction.

The thickness of the highly thermal conductive layer is preferably 40 to 550 μm, more preferably 60 to 530 μm, even more preferably 80 to 510 μm. When the thickness of the highly thermal conductive layer falls within the range, the layer can selectively radiate heat in a specific direction, and the thermoelectric element layers of a P-type thermoelectric element layer and an N-type thermoelectric element layer alternately and electrically connected in series to each other via an electrode can be thereby efficiently given a temperature difference in the in-plane direction of the layers.

The arrangement and the shape of the highly thermal conductive layer are not specifically limited, but need to be appropriately controlled in light of the thermoelectric element layers in the thermoelectric conversion module, that is, depending on the arrangement and the shape of the P-type thermoelectric element layer and the N-type thermoelectric element layer therein.

The proportion in which the highly thermal conductive layer is positioned relative to the overall width in the serial direction of a pair of a P-type thermoelectric element layer and an N-type thermoelectric element layer are independently preferably 0.30 to 0.70, more preferably 0.40 to 0.60, even more preferably 0.48 to 0.52, further more preferably 0.50. Falling within the range, heat can be selectively radiated in a specific direction, and a temperature difference can be efficiently given in the in-plane direction. Further, satisfying the above, it is preferable that the highly thermal conductive layers are positioned symmetrically relative to the joint region between a pair of a P-type thermoelectric element layer and an N-type thermoelectric element layer arranged in a serial direction. In such an alternate configuration of highly thermal conductive layers, a higher temperature difference can be given to the area between the joint of a pair of a P-type thermoelectric element layer and an N-type thermoelectric element layer in the in-plane serial direction and the joint of another pair of a P-type thermoelectric element layer and an N-type thermoelectric element layer adjacent to the former joint.

According to the production method for an intermediate for thermoelectric conversion modules of the present invention, an intermediate for thermoelectric conversion modules in which the thermoelectric element layer has been optimally annealed can be produced in a simple manner. Consequently, using the intermediate for thermoelectric conversion modules, a thermoelectric conversion module having improved thermoelectric performance can be produced.

### EXAMPLES

The present invention is described in more detail with reference to Examples, but the present invention is not whatsoever restricted by these Examples.

Evaluation of electric resistance, evaluation of output and evaluation of metal diffusion in thermoelectric element layer/electrode interface of the thermoelectric conversion modules produced in Examples and Comparative Examples were carried out according to the following methods.

### (a) Electric Resistance Value Evaluation

The electric resistance value between the takeout electrodes of thermoelectric element layers of the resultant thermoelectric conversion module was measured using Digital High Tester (by Hioki E.E. Corporation, Model Name: 3801-50) in an environment of 25° C.×50% RH.

### (b) Output Evaluation

One surface of the resultant thermoelectric conversion module was kept in a state heated at 50° C. with a hot plate and the other surface thereof was cooled at a temperature of 20° C. with a water-cooling heatsink, so that the thermoelectric conversion module was given a temperature difference of 30° C. Using Digital High Tester (by Hioki E.E. Corporation, Model Name: 3801-50), the voltage value (electromotive force) between the output takeout electrodes of the thermoelectric conversion module was measured.

### (c) Metal Diffusion Evaluation

Using a polishing device (by Refine Tec Ltd., Model Name: Refine Polisher HV), a cross section of the resultant thermoelectric conversion module was polished, and using FE-SEM/EDX (FE-SEM: by Hitachi High-Tech Corporation, Model Name: S-4700, EDX: by Oxford Instruments Corporation, Model Name: INCA x-stream), the thermoelectric element layer around the electrode in the module was checked for diffusion of electrode constituent elements in the layer.

### Example 1

### <Production of Thermoelectric Conversion Module>

A polymethyl methacrylate resin solution having a solid content of 10%, as prepared by dissolving a polymethyl methacrylate resin (PMMA) (by Sigma Aldrich Corporation, product name; polymethyl methacrylate) in toluene was applied to a glass substrate having a thickness of 0.7 mm (by Kawamura Kyuzo Shoten Co., Ltd., product name: Blue Sheet Glass) by spin coating to form a sacrificial layer thereon having a dry thickness of 1.0 μm.

Next, via a metal mask, a coating liquid (P) and a coating liquid (N) to be mentioned below were applied onto the sacrificial layer by screen printing so as to arrange thereon a P-type thermoelectric element layer and an N-type thermoelectric element layer alternately adjacent to each other (392 pairs of P-type thermoelectric element layer and N-type thermoelectric element layer each having a size of 1 mm×0.5 mm), and dried in an argon atmosphere at a temperature of 120° C. for 10 minutes to form a thin film having a thickness of 30 μm.

Subsequently, the resultant thin film was annealed in a mixed gas atmosphere of hydrogen and argon (hydrogen/argon=3 vol %/97 vol %) by heating at a heating rate of 5 K/min followed by keeping at 400° C. for 30 minutes for crystal growth of the fine particles of the thermoelectric semiconductor material to thereby form a P-type thermoelectric element layer and an N-type thermoelectric element layer each having a thickness of 30 μm.

Next, a nano silver paste (by Mitsuboshi Belting Ltd., product name: MDotEc264) was applied to the joint region stepping across the joint between the P-type thermoelectric element layer and the N-type thermoelectric element layer adjacent to each other, by screen printing, and heated and dried at 120° C. for 10 minutes to form an electrode having a thickness of 30 μm.

Next, a thermosetting sealant sheet (sealant layer: thickness 62 μm) formed according to the method mentioned below was stuck to the upper part of the P-type thermoelectric element layer and the N-type thermoelectric element layer, along with a highly thermal conductive layer formed according to the formulation and method mentioned below, in a mode of vacuum lamination, and then heated at 150° C. for 30 minutes to cure the thermosetting sealant (at the same time, the highly thermal conductive layer was adhered to the thermosetting sealant layer), and the silver electrode layer formed of the printed nano silver paste, and also the P-type thermoelectric element layer and the N-type thermoelectric element layer were peeled and transferred to the sealant layer.

Subsequently, similarly, a different thermosetting sealant sheet having the same formulation (sealant layer: thickness 60 μm) was stuck to the exposed surface of the peeled thermoelectric element layer, along with a different highly thermal conductive layer having the same formulation in a mode of vacuum lamination, and heat-treated at 150° C. for 30 minutes to cure the thermosetting sealant (at the same time, the highly thermal conductive layer was adhered to the thermosetting sealant layer) to thereby produce a thermoelectric conversion module not having a supporting substrate for the thermoelectric element layer.

### (Production Method for Thermoelectric Semiconductor Fine Particles)

A bismuth-tellurium-based thermoelectric semiconductor material, P-type bismuth telluride Bi_{0.4}Te₃Sb_{1.6} (by Kojundo Chemical Laboratory Co., Ltd., particle size: 180 μm) was ground in a nitrogen gas atmosphere using a planetary ball mill (by Fritsch Japan Co., Ltd., Premium Line P-7) to give thermoelectric semiconductor fine particles T1 having an average particle size of 2.0 μm. The resultant ground thermoelectric semiconductor fine particles were analyzed for particle size distribution, using a laser diffraction particle size analyzer (by Malvern Corporation, Mastersizer 3000).

A bismuth-tellurium-based thermoelectric semiconductor material, N-type bismuth telluride Bi₂Te₃ (by Kojundo Chemical Laboratory Co., Ltd., particle size: 180 μm) was ground in the same manner as above to prepare thermoelectric semiconductor fine particles T2 having an average particle size of 2.5 μm.

### (Production of Thermoelectric Semiconductor Composition)

### Coating Liquid (P)

95 parts by mass of the resultant P-type bismuth-tellurium-based thermoelectric semiconductor material fine particles T1, 2.5 parts by mass of a heat-resistant resin, polyimide precursor polyamic acid (by Sigma Aldrich Corporation, poly(pyromellitic acid dianhydride-co-4,4′-oxydianiline)amide acid solution, solvent: N-methylpyrrolidone, solid concentration: 15% by mass), and 2.5 parts by mass of an ionic liquid, N-butylpyridinium bromide were mixed and dispersed to prepare a coating liquid (P) of a thermoelectric semiconductor composition.

### Coating Liquid (N)

95 parts by mass of the resultant N-type bismuth-tellurium-based thermoelectric semiconductor material fine particles T2, 2.5 parts by mass of a heat-resistant resin, polyimide precursor polyamic acid (by Sigma Aldrich Corporation, poly(pyromellitic acid dianhydride-co-4,4′-oxydianiline)amide acid solution, solvent: N-methylpyrrolidone, solid concentration: 15% by mass), and 2.5 parts by mass of an ionic liquid, N-butylpyridinium bromide were mixed and dispersed to prepare a coating liquid (N) of a thermoelectric semiconductor composition.

### (Formation of Thermosetting Sealant Sheet)

To both surfaces of an insulating layer (PET, thickness: 12 μm), an epoxy adhesive sheet formed of a composition containing a thermoplastic resin and an epoxy resin (by Somar Corp., EP-0002EF-01 MB, thickness: 24 μm) was stuck by lamination to form a thermosetting sealant sheet.

### (Mounting of Highly Thermal Conductive Layer)

Like in FIG. 2(b), a highly thermal conductive layer (oxygen-free copper JIS H 3100, C1020, thickness: 100 μm, width: 1 mm, length: 100 mm, spacing: 1 mm, thermal conductivity: 398 (W/m·K)) was arranged on the surface of the sealant layer 5A and the sealant layer 5B in such a manner that striped highly thermal conductive layer 6A and highly thermal conductive layer 6B having the same formulation could be arranged alternatively on the upper part and the lower part shown in FIG. 2(b) of the joint region adjacent to the P-type thermoelectric element layer 3b and the N-type thermoelectric element layer 3a and in such a manner that the highly thermal conductive layer 6A and the highly thermal conductive layer 6B could align symmetrically via the joint region to produce a thermoelectric conversion module (having the same configuration as in FIG. 2(b)). Next, the thermoelectric conversion module was so configured that it could be heated from the side of the highly thermal conductive layer 6A and cooled from the side of the highly thermal conductive layer 6B.

### Comparative Example 1

According to the following process, a thermoelectric conversion module having a configuration of Comparative Example 1 was produced. First, on an electrode-attached film substrate, as prepared by forming an electrode pattern of copper-nickel-gold laminated in that order (copper 9 μm, nickel 9 μm, gold 0.04 μm, thermal conductivity 148 W/(m·K)) on a square polyimide film of 100 mm×100 mm (by Toray DuPont Corporation, Kapton 200H, thickness 50 μm, thermal conductivity 0.16 W/(m·K)), a P-type thermoelectric conversion material (the above-mentioned P-type bismuth-tellurium-based thermoelectric semiconductor material) and an N-type thermoelectric conversion material (the above-mentioned N-type bismuth-tellurium-based thermoelectric semiconductor material) were arranged alternately adjacent to each other. 14 pairs of the two thermoelectric conversion materials of 1 mm×0.5 mm in one row were folded to give a thermoelectric conversion module having 28 rows of 392 pairs of the materials. The thermal conductivity of the thermoelectric element layer was 0.25 W/(m·K). The resultant thermoelectric conversion module was heated in a mixed gas atmosphere of hydrogen and argon (hydrogen/argon=3 vol %/97 vol %) by heating at a heating rate of 5 K/min and kept at 400° C. for 30 minutes to anneal the thin film for crystal growth of the fine particles of the thermoelectric semiconductor material to thereby form a P-type thermoelectric element layer and an N-type thermoelectric element layer each having a thickness of 30 μm.

The thermoelectric conversion modules produced in Example 1 and Comparative Example 1 were evaluated in point of metal diffusion into the thermoelectric element layer, the electric resistance value and the output power. The evaluation results are shown in Table 1.

TABLE 1

| | Thermoelectric Conversion Module | | | | | | |
|---|---|---|---|---|---|---|---|
| | | | | Ni Diffusion into | | | |
| | | | | Thermoelectric | | Electric | |
| | | | Annealing | Element Layer | | Resistance | Output |
| | | Supporting | Treatment | (atm %) | | Value | Evaluation |
| | Configuration | Substrate | Condition | p-type | n-type | (Ω) | (V) |
| Example 1 | In-Plane Type | — | No joint to | 0 | 0 | 24 | 0.32 |
| | [FIG. 2(b)] | | electrode | | | | |
| Comparative | In-Plane | polyimide | With joint | 14 | 39 | *O.L. | — |
| Example 1 | Type | | to electrode | | | | |

*OL.: overflow level

It is known that, in Comparative Example 1 where the thermoelectric element layer was annealed at an optimum annealing temperature in a state having a joint to electrode, the Ni element constituting the electrode diffused in the thermoelectric element layer and, in addition, the supporting substrate of polyimide shrank at a high temperature so that the thermoelectric element layer peeled and broke, and therefore the module could no more be evaluated, but in Example 1 where the thermoelectric element layer was annealed at an optimum annealing temperature in a state not having a joint to electrode, the module could be evaluated for electric properties and output power with no problem.

### INDUSTRIAL APPLICABILITY

According to the production method for an intermediate for thermoelectric conversion modules of the present invention, there can be produced an intermediate for thermoelectric conversion modules which does not require a conventional supporting substrate, which enables annealing treatment of a thermoelectric semiconductor material in a form not having a joint to an electrode, and which enables annealing of a thermoelectric semiconductor material at an optimum annealing temperature. Further, using the intermediate for thermoelectric conversion modules, there can be produced a thermoelectric conversion module having high-level thermoelectric performance. Consequently, as compared with already-existing ones, the thermoelectric conversion module to be produced in the invention is expected to have improved power generation efficiency and improved cooling efficiency, and is therefore expected to contribute toward downsizing and cost reduction. In addition, the thermoelectric conversion module of the present invention can be installed in various installation sites with no specific limitation, for example, for waste heat sources or radiation sources having uneven faces.

### REFERENCE SIGNS LIST

1: Substrate
2: Sacrificial Layer
3a: N-type Thermoelectric Element Layer
3b: P-type Thermoelectric Element Layer
4: Electrode
5A: Sealant Layer
5B: Sealant Layer
6A: Highly Thermal Conductive Layer
6B: Highly Thermal Conductive Layer

1. A method for producing an intermediate for thermoelectric conversion modules that contains a P-type thermoelectric element layer and an N-type thermoelectric element layer of a thermoelectric semiconductor composition, the method comprising:
(A) forming the P-type thermoelectric element layer and the N-type thermoelectric element layer on a substrate,
(B) annealing the P-type thermoelectric element layer and the N-type thermoelectric element layer formed in the forming (A),
(C) forming a sealant layer containing a curable resin or a cured product thereof, on the P-type thermoelectric element layer and the N-type thermoelectric element layer annealed in the annealing (B), and
(D) peeling the P-type thermoelectric element layer and the N-type thermoelectric element layer and also the sealant layer formed in annealing (B) and forming (C) from the substrate.

2. The method of claim 1, further comprising:
forming an electrode on the annealed P-type thermoelectric element layer and N-type thermoelectric element layer.

3. The method of claim 1, wherein the curable resin is a thermosetting resin or an energy ray-curable resin.

4. The method of claim 1, wherein the curable resin is an epoxy resin.

5. The method of claim 1, wherein the substrate is a glass substrate.

6. The method of claim 1, wherein the thermoelectric semiconductor composition contains a thermoelectric semiconductor material and the thermoelectric semiconductor material is a bismuth-tellurium-based thermoelectric semiconductor material, a telluride-based thermoelectric semiconductor material, an antimony-tellurium-based thermoelectric semiconductor material, or a bismuth-selenide-based thermoelectric semiconductor material.

7. The method of claim 1, wherein the thermoelectric semiconductor composition further contains a heat-resistant resin, and an ionic liquid and/or an inorganic ionic compound.

8. The method of claim 1, wherein the heat-resistant resin is a polyimide resin, a polyamide resin, a polyamideimide resin or an epoxy resin.

9. The method of claim 1, wherein the annealing temperature is in a range of from 250 to 600° C.
